(19) United States
(12) Patent Application Publication
(10) Pub. No.: US 2007/0278480 A1
(43) Pub. Date: Dec. 6, 2007

(54) Organic light emitting display and method of manufacturing the same

(76) Inventors: Eui-Hoon Hwang, Suwon-si (KR); Woong-Sik Choi, Suwon-si (KR)

Correspondence Address: Robert E. Bushnell, Suite 300, 1522 K Street, N.W., Washington, DC, 20005, US

(21) Appl. No.: 11/651,461

(22) Filed: Jan. 10, 2007

(30) Foreign Application Priority Data
Jun. 2, 2006 (KR) 10-2006-0049641

(51) Int. Cl. H01L 29/08

(52) U.S. Cl. 257/40

(57) ABSTRACT

In an organic light emitting display, the process of forming a storage capacitor is simplified, and deterioration of the properties and the reliability of the TFT is prevented. The organic light emitting display includes a substrate, a thin film transistor formed on one portion of the substrate, the thin film transistor having an active layer, a gate electrode, a gate insulating layer interposed between the active layer and the gate electrode, and a storage capacitor formed on another portion of the substrate. The storage capacitor has a first electrode formed on the same surface as the active layer, and a second electrode formed on the same surface as the gate electrode, with the gate insulating layer being interposed between the first electrode and the second electrode. The active layer and the first electrode are made of an intrinsic polysilicon layer.

### CLAIM OF PRIORITY

This application makes reference to, incorporates the same herein, and claims all benefits accruing under 35 U.S.C. §119 from an application earlier filed in the Korean Intellectual Property Office on 2 Jun. 2006 and there duly assigned Serial No. 10-2006-0049641.

### BACKGROUND OF THE INVENTION

1. Field of the Invention

The present invention relates to an organic light emitting display, and more particularly to an organic light emitting display having a storage capacitor and a method of manufacturing the same.

2. Description of the Related Art

Display devices such as the organic light emitting display and the liquid crystal display, which are small in thickness and operate with low voltage, unlike the cathode ray tube (CRT) which is bulky and operates with high voltages, are being widely used as the next generation of display device.

Particularly, the organic light emitting display is a self-emitting display device in which electrons and holes injected into organic material through an anode and a cathode are recombined to generate excitons, and light with a certain wavelength is emitted as a result of the energy of the generated excitons. Accordingly, the organic light emitting display is being highlighted as the next generation of display device since it does not require a separate light source such as a backlight, and thus it is low in its power consumption, as compared to the liquid crystal display. In addition, it may secure a wide viewing angle and a high response speed easily.

The organic light emitting display, which may be divided into a passive matrix type and an active matrix type depending on the driving method, has mainly employed the active matrix type in recent years due to its low power consumption, high precision, high response speed, wide viewing angle and small thickness.

In such an active matrix type organic light emitting display, pixels as the basic unit for image representation are arranged on a substrate in the form of a matrix. A light emitting element having a structure wherein a first electrode of an anode, a light emitting layer and a second electrode of a cathode are stacked in order is arranged for each of the pixels. The light emitting layer is made of an organic material making red(R), green(G) and blue(B) colors, respectively. A thin film transistor (TFT) connected to the light emitting element and a storage capacitor are arranged for each of the pixels so as to control the pixels separately.

The storage capacitor may generally be formed at the same that the TFT is manufactured. For example, the first and second electrodes of the storage capacitor may be formed when forming an active layer and a gate electrode, respectively, of the TFT. The active layer is made of a polycrystalline silicon (polysilicon) layer to be crystallized by annealing an amorphous silicon layer at low temperature (e.g., ≦600° C.) after depositing the amorphous silicon on a substrate. The first electrode of the storage capacitor is made of an N⁺ doped polysilicon layer.

If the above described organic light emitting display has only P-channel MOS (PMOS) TFTs, a separate mask process is required to dope N⁺ impurities into the first electrode of the storage capacitor. As a result, there are problems in that the manufacturing process of the organic light emitting display is complicated and cost is enhanced.

On the other hands, if the above described organic light emitting display has complementary MOS TFTs including PMOS TFTs, and N-channel MOS (NMOS) TFTs, it does not require a separate mask process because the N⁺ impurities may be doped into the first electrode of the storage capacitor at the same time as N⁺ source and drain regions of the NMOS TFT are formed. However, since this doping process of N⁺ impurities is performed before forming gate electrodes in the CMOS TFT, the doped N⁺ impurities may be unnecessarily diffused when forming the gate electrodes. As a result, there are problems in that the properties and the reliability of the CMOS TFTs are deteriorated, thereby degrading the display quality of the organic light emitting display.

### SUMMARY OF THE INVENTION

The present invention has been developed to overcome the above and other problems, and it is an object of the present invention to provide an organic light emitting display which is capable of simplifying process of forming a storage capacitor and preventing the properties and the reliability of the TFT from deteriorating.

It is also an object of the present invention to provide a method of manufacturing the organic light emitting display of the present invention.

According to one aspect of the present invention, an organic light emitting display includes a substrate, a thin film transistor formed on one portion of the substrate, the thin film transistor having an active layer, a gate electrode and a gate insulating layer interposed between the active layer and the gate electrode, and a storage capacitor formed on the other portion of the substrate, the storage capacitor having a first electrode formed on the same surface as the active layer and a second electrode formed on the same surface as the gate electrode with the gate insulating layer interposed between the first electrode and the second electrode, the active layer and the first electrode being made of an intrinsic polysilicon layer, respectively.

The resistance of the intrinsic polysilicon layer is 1E8 to 1E11Ω.

The active layer and the first electrode are formed below the gate electrode and the second electrode, respectively.

The organic light emitting display further includes a light emitting element formed over the thin film transistor.

The light emitting element has a structure wherein a first electrode, an organic light emitting layer and a second electrode are stacked in order.

The gate insulating layer has a structure wherein a silicon nitride layer and a silicon oxide layer are stacked in order.

The present invention also contemplates a method of manufacturing an organic light emitting display, comprising the steps of providing a substrate where a first region for a PMOS thin film transistor and a second region for a storage capacitor are defined, forming an intrinsic polysilicon layer on the substrate, patterning the intrinsic polysilicon layer to form an active layer on the first region and to form a first electrode on the second region, forming a gate insulating layer on the entire surface of the substrate so as to cover the active layer and the first electrode, forming a gate electrode and a second electrode on the gate insulating layer corresponding to the active layer and the first electrode, respectively, and forming P⁺ impurity regions in both sides of the active layer.

Furthermore, the present invention contemplates a method of manufacturing an organic light emitting display, comprising the steps of providing a substrate where a first region for a first MOS thin film transistor of a first conductive type, a second region for a second MOS thin film transistor of a second conductive type opposite to the first conductive type, and a third region for a storage capacitor are defined, forming an intrinsic polysilicon layer on the entire surface of the substrate, patterning the intrinsic polysilicon layer to form first and second active layers on the first and second regions, respectively and to form a first electrode on the third region, forming a gate insulating layer on the entire surface of the substrate so as to cover the first and second active layers and the first electrode, forming first and second gate electrodes on the gate insulating layer corresponding to the first and second active layers, respectively, forming a second electrode on the gate insulating layer corresponding the first electrode, and forming impurity regions of the first conductive type in both sides of the first active layer, and forming impurity regions of the second conductive type in both sides of the second active layer.

The resistance of the intrinsic polysilicon layer is 1E8 to 1E11Ω.

The intrinsic polysilicon layer is formed by depositing an amorphous silicon layer using a plasma enhanced chemical vapor deposition (PECVD) process, and by performing an annealing process such as a furnace annealing or an excimer laser annealing (ELA).

The gate insulating layer has a structure wherein a silicon nitride layer and a silicon oxide layer are stacked in order.

The first conductive type is N type, and the second conductive type is P type, or when the first conductive type is P type, the second conductive type is N type.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic view showing an organic light emitting display according to an embodiment of the present invention;

FIG. 2 is a partial sectional view showing a pixel of the organic light emitting display;

FIG. 3 is a graph showing the capacitance of a storage capacitor in the organic light emitting display and the capacitance of a comparative example.

FIGS. 4A thru 4C are process views showing a first method of manufacturing the manufacturing the organic light emitting display.

FIGS. 5A thru 5D are process views showing a second method of manufacturing the organic light emitting display.

### DETAILED DESCRIPTION OF THE EMBODIMENTS

The present invention will now be described more fully with reference to the accompanying drawings, in which exemplary embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to those skilled in the art.

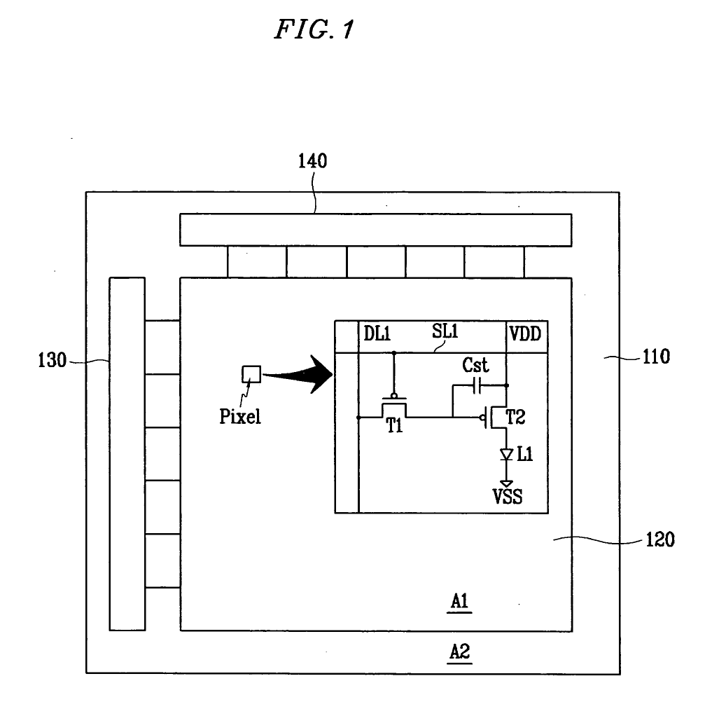

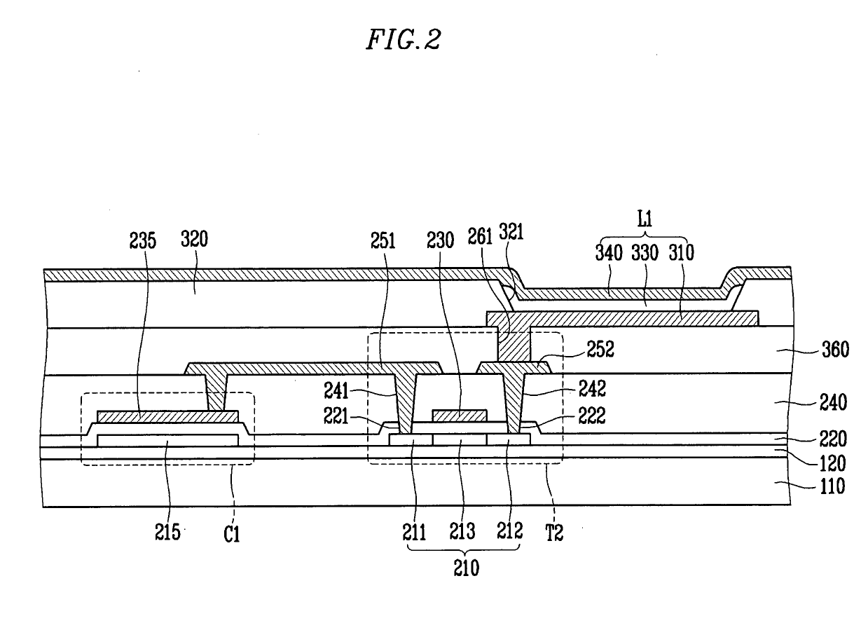

An organic light emitting display according to an embodiment of the present invention will now be described with reference to FIG. 1 which is a schematic view showing an organic light emitting display according to an embodiment of the present invention, and with reference to FIG. 2 which is a partial sectional view showing a pixel of the organic light emitting display.

Referring to FIG. 1, a pixel region A1 for light emitting or image representation is formed on a substrate 110, and a non-pixel region A2 is formed on the substrate 110 surrounding the pixel region A1. Pixels are arranged in the form of a matrix in the pixel region A1. A scan line driving region 130 for driving a scan line SL1 of the pixel, and a data line driving region 140 for driving a data line DL1 of the pixel, are formed in the non-pixel region A2.

The substrate 110 can be made of an insulating material such as glass or plastic, or a metal material such as stainless steel (SUS). When the substrate 110 is made of metal material, an insulating layer is further formed on the substrate 110.

For example, as illustrated in FIG. 1, the pixel includes first and second TFTs T1 and T2, respectively, of a PMOS, a storage capacitor Cst, and a light emitting element L1. However, the type and the number of the TFTs and the number of the storage capacitors forming the pixel are not limited to the illustration, but may be altered in various ways.

Describing the pixel in more detail, the first TFT T1 is connected to the scan line SL1 and the data line DL1 and transmits data voltage inputted from the data line DL1 to the second TFT T2 depending on the switching voltage inputted from the scan line SL1. The storage capacitor Cst is connected to the first TFT T1 and a power line VDD, and stores the voltage Vgs corresponding to the difference between the voltage transmitted from the first TFT T1 and the voltage applied to the power line VDD. The second TFT T2 is connected to the power line VDD and the storage capacitor Cst, and supplies the output current Id which is in proportion to the square of a voltage corresponding to the difference between the voltage stored in the storage capacitor Cst and the threshold voltage Vth for the light emitting element L1. The light emitting element L1 is emitted by the output current Id. The output current Id satisfies the following equation (1), where β is the scaling value:

I_{d}=(β/2)×(V_{gs}−Vₜₕ)² equation (1)

The TFT T2, the storage capacitor Cst and the light emitting element L1 will be described in more detail with reference to FIG. 2.

A buffer layer 120 is formed on the substrate 110. An active layer 210 and a first electrode 215 are respectively formed on the buffer layer 120. The active layer 210 has a source region 211 and drain region 212 with a channel region 213 therebetween. A gate insulating layer 220 is formed on the entire surface of the substrate 110 so as to cover the active layer 210 and the first electrode 215. A gate electrode 230 is formed on the gate insulating layer 220 in correspondence to the channel region 213 of the active layer 210. A second electrode 235 is formed on the gate insulating layer 220 in correspondence to the first electrode 215. The first electrode 215 and the second electrode 235, with the gate insulating layer 220 therebetween, form the storage capacitor Cst. An intermediate insulating layer 240 is formed on the gate insulating layer 220 so as to cover the gate electrode 230 and the storage capacitor Cst. Source electrode 251 and drain electrode 252 are formed on the intermediate insulating layer 240. The source and drain electrodes 251 and 252, respectively, are electrically connected to the source and drain regions 211 and 212, respectively, through first contact holes 221 and 241 and second contact holes 222 and 242, respectively, provided in the intermediate insulating layer 240 and the gate insulating layer 220. The active layer 210, the gate insulating layer 220, the gate electrode 230 and the source and drain electrodes 211 and 212, respectively, form the TFT T2. The source electrode 251 is also electrically connected to the second electrode 235 of the storage capacitor Cst through a third contact hole 242 provided in the intermediate insulating layer 240.

The buffer layer 120 is preferably a silicon nitride (SiN) layer or a structure wherein a silicon nitride (SiN) layer and a silicon oxide (SiO₂) layer are stacked.

The active layer 210 and the first electrode 215 are made of an intrinsic polysilicon layer having a resistance of 1E8 to 1E11Ω. The source and drain regions 211 and 212, respectively, can be doped by P⁺ impurities.

Since many defects existing in the interface and the grain boundary of the intrinsic polysilicon layer have a low energy level, unlike a single crystalline silicon layer, they can act as free carriers with low energy. Therefore, the intrinsic polysilicon layer can be applied to the first electrode 215 of the storage capacitor Cst.

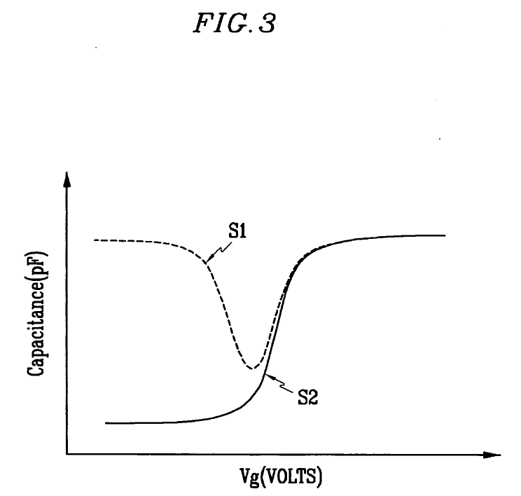

FIG. 3 is a graph showing the capacitance of a storage capacitor in the organic light emitting display and the capacitance of a comparative example. More specifically, FIG. 3 shows the capacitance S1 of the storage capacitor Cst, according to this embodiment, as measured in the high frequency band of 100 KHz, and the capacitance S2 of a storage capacitor, according to a comparative example, as measured in the high frequency band of 1 MHz or more. It can be proved by FIG. 3 that the storage capacitor Cst of this embodiment has an inverted capacitance.

The gate insulating layer 220 of FIG. 2 has a structure wherein a silicon nitride (SiN) layer and a silicon oxide (SiO₂) layer are stacked in order. The thickness of the silicon nitride layer is approximately 400 Å and the thickness of the silicon oxide layer is approximately 800 Å.

The gate electrode 230 and the second electrode 235 are made of the same material. For example, they are made of a metal layer such as MoW, Al, Cr or Al/Cr.

Furthermore, a planarizing layer 360 is formed on the intermediate insulating layer 240 so as to cover the TFT T2 of FIG. 2. A light emitting element L1 is formed on the planarizing layer 260. The light emitting element L1 has a structure wherein a first electrode 310, an organic light emitting layer 330 and a second electrode 340 are stacked in order. The first electrode 310 is electrically connected to the drain electrode 252 of the TFT T2 through a via hole 261 provided in the planarizing layer 260.

The first electrode 310 of the light emitting element L1 is isolated from first electrodes (not shown) of adjacent pixels by a pixel definition layer 320, and contacts the organic light emitting layer 330 through the opening 321 provided in the pixel definition layer 320.

The first electrode 310 and the second electrode 320 can be made of indium Tin oxide (ITO), indium zinc oxide (IZO), Al, Mg—Ag, Ca, Ca/Ag or Ba, or a combination thereof.

The organic light emitting layer 330 can be made of a low molecule organic material or a high molecule organic material. Alternatively, the organic light emitting layer 330 has a hole injection layer (HIL), a hole transport layer (HTL), an electron injection layer (EIL) and an electron transport layer (ETL).

Although not shown in FIG. 1, each of the scan line driving region 130 and the data line driving region 140 of the non-pixel region A2 can be made of a plurality of PMOS TFTs or CMOS TFTs.

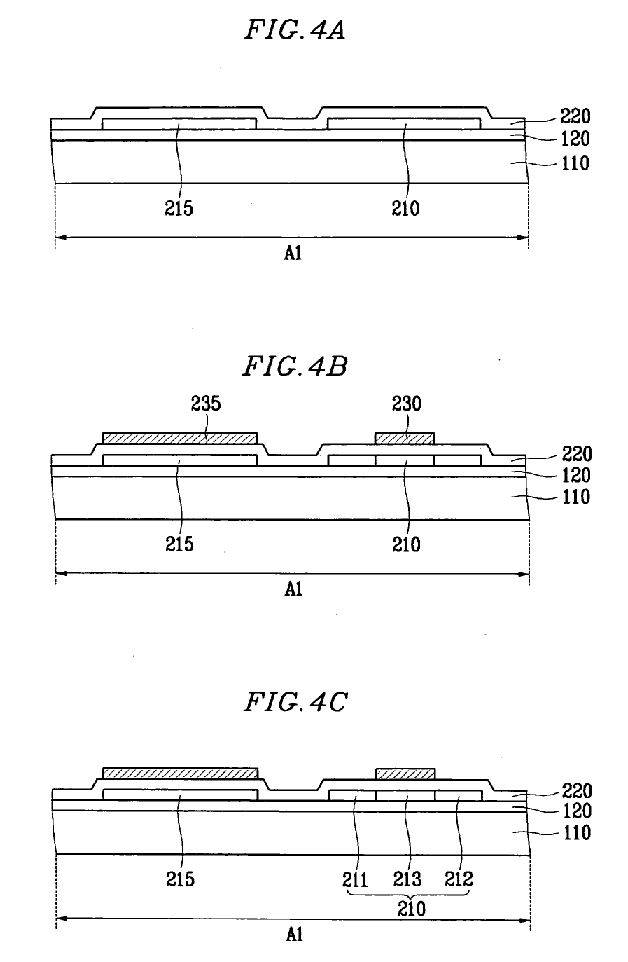

A first method of manufacturing the organic light emitting display will be described with reference to FIGS. 4A thru 4C, which are process view showing first method of manufacturing the manufacturing the organic light emitting display. The first method relates to the case wherein the organic light emitting display only has PMOS TFTs, and FIGS. 4A thru 4C show a storage capacitor region and a PMOS TFT region in the pixel region A1.

Referring to FIG. 4A, the buffer layer 120 is formed on the substrate 110. The buffer layer 120 is made of a silicon nitride layer (SiN) or has a structure wherein a silicon nitride (SiN) layer and a silicon oxide (SiO₂) layer are stacked. An intrinsic polysilicon layer having a resistance of 1E8 to 1E11Ω is formed on the buffer layer 120 and is patterned so as to form the active layer 210 in the PMOS TFT region and to form the first electrode in the storage capacitor region.

The intrinsic polysilicon layer is formed by depositing an amorphous silicon layer on the buffer layer 120 using a plasma enhanced chemical vapor deposition (PECVD) process and performing an annealing process, such as furnace annealing or excimer laser annealing (ELA). At this point, the buffer layer 120 prevents impurities of the substrate 110 from diffusing into the amorphous silicon layer.

Next, the gate insulating layer 220 is formed on an entire surface of the substrate 110 so as to cover the active layer 210 and the first electrode 215. The gate insulating layer 220 has a structure wherein the silicon nitride (SiN) layer and the silicon oxide (SiO₂) layer are stacked in order. The thickness of the silicon nitride layer is approximately 400 Å and the thickness of the silicon oxide layer is approximately 800 Å.

Referring to FIG. 4B, a metal layer such as MoW, Al, Cr or Al/Cr is deposited on the gate insulating layer 220 and is patterned to form gate electrode 230 corresponding to a center portion (i.e., the channel region, refer to FIG. 4C) of the active layer 210, and second electrode 235 corresponding to the first electrode 215. As a result, the storage capacitor Cst (refer to FIG. 2) is formed in the pixel region A1 of the substrate 100.

Referring to FIG. 4C, P⁺ impurities are doped into both sides of the active layer 210 using a mask process and an ion-implanting process so as to form the P+ source and drain regions 211 and 212, respectively.

Thereafter, the intermediate insulating layer 240 (refer to FIG. 2), the source and drain electrodes 251 and 252, respectively (refer to FIG. 2), the planarizing layer 260 (refer to FIG. 2), the pixel definition layer 320 (refer to FIG. 2) and the light emitting element L1 (refer to FIG. 2), are formed by well-known methods.

Thus, in this method of manufacturing the organic light emitting display, since the first electrode 215 of the storage capacitor Cst is made of an intrinsic polysilicon layer, a separate doping process for the first electrode 215 can be omitted. As a result, the manufacturing process of the organic light emitting display is simplified.

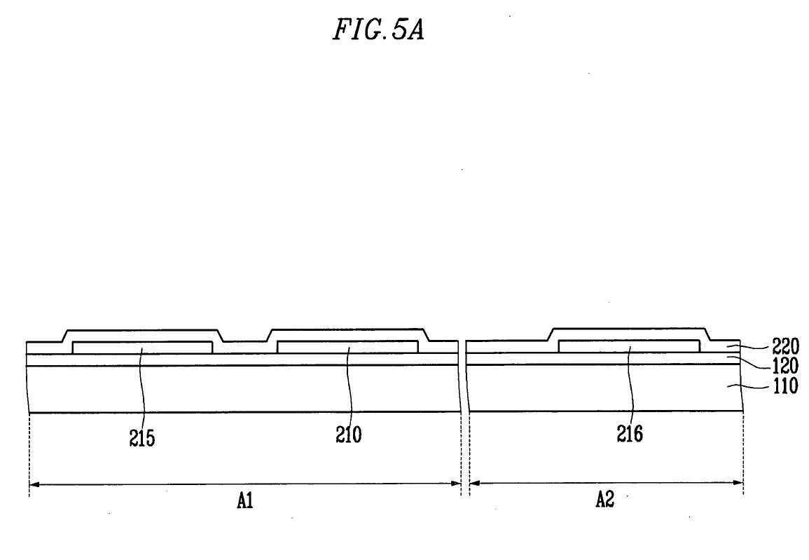

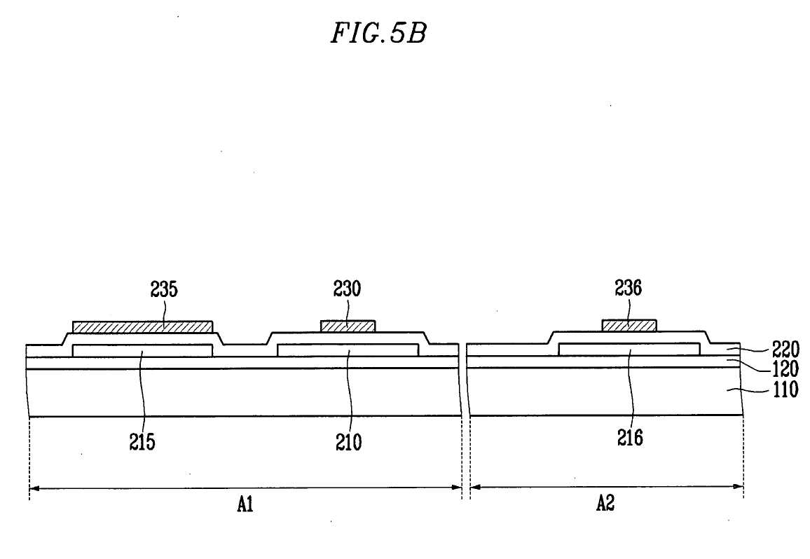

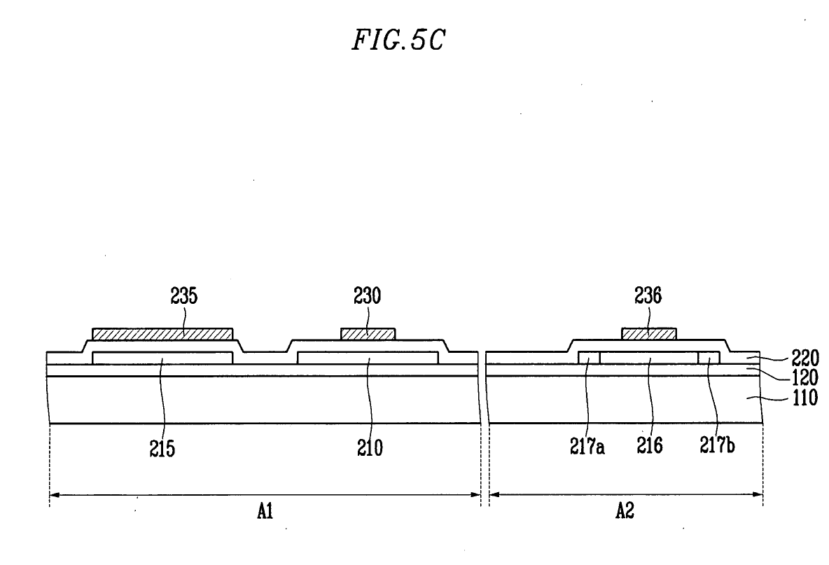

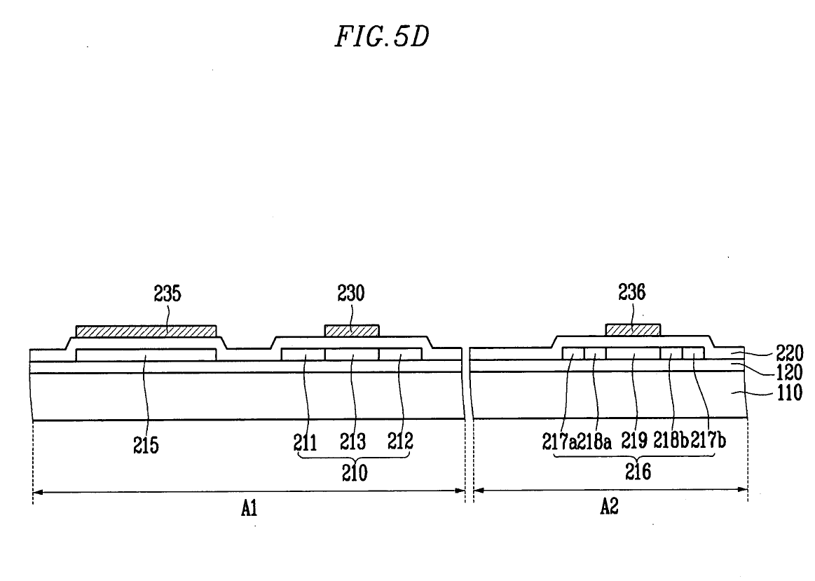

A second method of manufacturing the organic light emitting display will be described with reference to FIGS. 5A thru 5D which are process views showing a second method of manufacturing the organic light emitting display. The second method shows the case wherein the organic light emitting display has CMOS TFTs. FIGS. 5A thru 5D show a storage capacitor region and a PMOS TFT region in the pixel region A1 and a NMOS TFT region in the non-pixel region A2.

Referring to FIG. 5A, the buffer layer 120 is formed on the substrate 110. The buffer layer 120 is a silicon nitride layer (SiNx) or has a structure wherein a silicon nitride (SiN) layer and a silicon oxide (SiO₂) layer are stacked. The intrinsic polysilicon layer having a resistance of 1E8 to 1E11Ω is formed on the buffer layer 120 and is patterned to form active layers 210 and 216 in the PMOS TFT region and the NMOS TFT region, respectively, and to form the first electrode 215 in the storage capacitor region.

The intrinsic polysilicon layer is formed by depositing an amorphous silicon layer on the buffer layer 120 using a PECVD process, and performing an annealing process such as furnace annealing or ELA. At this point, the buffer layer 120 prevents impurities of the substrate 110 from diffusing into the amorphous silicon layer.

Next, the gate insulating layer 200 is formed on the entire surface of the substrate 110 so as to cover the active layers 210 and 216 and the first electrode 214. The gate insulating layer 220 has a structure wherein the silicon nitride (SiNx) layer and the silicon oxide (SiO₂) layer are stacked in order. The thickness of the silicon nitride layer is approximately 400 Å and the thickness of the silicon oxide layer is approximately 800 Å.

Referring to FIG. 5B, a metal layer such as MoW, Al, Cr or Al/Cr is deposited on the gate insulating layer 220 and is patterned to form the gate electrodes 230 and 236 corresponding to center portions (i.e. channel regions, refer to FIG. 5C) of the active layers 210 and 216, respectively, and the second electrode 235 corresponding to the first electrode 215. As a result, the storage capacitor Cst (refer to FIG. 2) is formed in the pixel region A1 of the substrate 100.

Referring to FIG. 5C, N⁺ impurities are doped into both sides of the active layer 216 in the NMOS TFT region using a mask process and an ion-implanting process to form N⁺ source and drain regions 217a and 217b, respectively.

Referring to FIG. 5D, P⁺ impurities are doped into both sides of the active layer 210 in the PMOS TFT region using a mask process and an ion-implanting process, to form P⁺ source and drain regions 211 and 212, respectively. LDD regions 218a and 218b are then formed inside the N⁺ source and drain regions 217a and 217b, respectively, in the NMOS TFT region.

In this method, although the P⁺ source and drain regions 211 and 212, respectively, are formed after forming the N⁺ source and drain regions 217a and 217b, respectively, it is also possible that N⁺ source and drain regions 217a and 217b, respectively, be formed after forming the P+ source and drain regions 211 and 212, respectively.

Thereafter, the intermediate insulating layer 240 (refer to FIG. 2), the source and drain electrodes 251 and 252, respectively (refer to FIG. 2), the planarizing layer 260 (refer to FIG. 2), the pixel definition layer 320 (refer to FIG. 2) and the light emitting element L1 (refer to FIG. 2) are formed by well-known methods.

Thus, in this method of manufacturing the organic light emitting display, since the first electrode 215 of the storage capacitor Cst is made of an intrinsic polysilicon layer, a separate doping process for the first electrode 215 can be omitted. Therefore, although the organic light emitting display includes CMOS TFTs, the doping process of N⁺ impurities can be performed after forming the gate electrodes 230 and 236. As a result, the process can be controlled so that the N⁺ impurities are not unnecessarily diffused, thereby preventing the properties and the reliability of the TFT from deteriorating.

Although preferred embodiments of the present invention have been shown and described, it will be appreciated by those skilled in the art that changes may be made in these embodiments without departing from the principles and spirit of the invention, the scope of which is defined in the claims and their equivalents.

What is claimed is:

1. An organic light emitting display, comprising:
a substrate;
a thin film transistor formed on one portion of the substrate, the thin film transistor having an active layer, a gate electrode, and a gate insulating layer interposed between the active layer and the gate electrode; and
a storage capacitor formed on another portion of the substrate, the storage capacitor having a first electrode formed on a same surface as the active layer is formed, and a second electrode formed on a same surface as the gate electrode is formed, with the gate insulating layer being interposed between the first electrode and the second electrode;
wherein the active layer and the first electrode are made of an intrinsic polysilicon layer.

2. The organic light emitting display of claim 1, wherein a resistance of the intrinsic polysilicon layer is in a range of 1E8 to 1E11Ω.

3. The organic light emitting display of claim 1, wherein the active layer and the first electrode are formed below the gate electrode and the second electrode, respectively.

4. The organic light emitting display of claim 1, further comprising a light emitting element formed over the thin film transistor.

5. The organic light emitting display of claim 4, wherein the light emitting element comprises a first electrode, an organic light emitting layer, and a second electrode which are stacked in order.

6. The organic light emitting display of claim 1, wherein the gate insulating layer comprises a silicon nitride layer and a silicon oxide layer which are stacked in order.

7. A method of manufacturing an organic light emitting display, comprising the steps of:
providing a substrate wherein a first region for a PMOS thin film transistor and a second region for a storage capacitor are defined;
forming an intrinsic polysilicon layer on the substrate;
patterning the intrinsic polysilicon layer to form an active layer in the first region and to form a first electrode in the second region;
forming a gate insulating layer on an entire surface of the substrate so as to cover the active layer and the first electrode;
forming a gate electrode and a second electrode on the gate insulating layer in correspondence to the active layer and the first electrode, respectively; and
forming P+ impurity regions in both sides of the active layer.

8. The method of claim 7, wherein a resistance of the intrinsic polysilicon layer is in a range of 1E8 to 1E11Ω.

9. The method of claim 8, wherein the step of forming the intrinsic polysilicon layer comprises depositing an amorphous silicon layer using a plasma enhanced chemical vapor deposition (PECVD) process, and performing an annealing process.

10. The method of claim 9, wherein the annealing process is performed by means of one of furnace annealing and excimer laser annealing (ELA).

11. The method of claim 7, wherein the step of forming the gate insulating layer comprises stacking a silicon nitride layer and a silicon oxide layer in order.

12. A method of manufacturing an organic light emitting display, comprising the steps of:
providing a substrate wherein a first region for a first MOS thin film transistor of a first conductive type, a second region for a second MOS thin film transistor of a second conductive type opposite to the first conductive type, and a third region for a storage capacitor are defined;
forming an intrinsic polysilicon layer on an entire surface of the substrate;
patterning the intrinsic polysilicon layer to form first and second active layers in the first and second regions, respectively and to form a first electrode in the third region;
forming a gate insulating layer on an entire surface of the substrate so as to cover the first and second active layers and the first electrode;
forming first and second gate electrodes on the gate insulating layer in correspondence to the first and second active layers, respectively and forming a second electrode on the gate insulating layer in correspondence the first electrode;
forming impurity regions of the first conductive type in both sides of the first active layer; and
forming impurity regions of the second conductive type in both sides of the second active layer.

13. The method of claim 12, wherein a resistance of the intrinsic polysilicon layer is in a range of 1E8 to 1E11Ω.

14. The method of claim 13, wherein the step of forming the intrinsic polysilicon layer comprises depositing an amorphous silicon layer using a plasma enhanced chemical vapor deposition (PECVD) process, and performing an annealing process.

15. The method of claim 14, wherein the annealing process is performed by means of one of furnace annealing and excimer laser annealing (ELA).

16. The method of claim 12, wherein the step of forming the gate insulating layer comprises stacking a silicon nitride layer and a silicon oxide layer in order.

17. The method of claim 12, wherein when the first conductive type is an N type, the second conductive type is a P type, and when the first conductive type is a P type, the second conductive type is an N type.
